(19) United States
(12) Patent Application Publication
(10) Pub. No.: US 2018/0233562 A1
(43) Pub. Date: Aug. 16, 2018

(54) SILICON CARBIDE EPITAXIAL SUBSTRATE

(71) Applicant: SUMITOMO ELECTRIC INDUSTRIES, LTD., Osaka-shi, Osaka (JP)

(72) Inventors: Taro NISHIGUCHI, Itami-shi (JP); Keiji WADA, Itami-shi (JP); Jun GENBA, Itami-shi (JP); Hironori ITOH, Itami-shi (JP); Hideyuki DOI, Itami-shi (JP); Kenji HIRATSUKA, Itami-shi (JP)

(21) Appl. No.: 15/516,148

(22) PCT Filed: Aug. 18, 2015
(86) PCT No.: PCT/JP2015/073134

§ 371 Date: Mar. 31, 2017

(30) Foreign Application Priority Data
Oct. 1, 2014 (JP) 2014-203159
Nov. 6, 2014 (JP) 2014-226077
Dec. 25, 2014 (JP) 2014-262111

(51) Int. Cl. H01L 29/16; C30B 25/20; C30B 29/36; H01L 21/02; H01L 29/34

(52) U.S. Cl. CPC H01L 29/1608; C30B 25/20; C30B 29/36; H01L 29/34; H01L 21/02529; H01L 21/0262; H01L 21/02634; H01L 21/02378

(57) ABSTRACT

A silicon carbide epitaxial substrate includes: a silicon carbide single crystal substrate; and an epitaxial layer. The silicon carbide single crystal substrate has a diameter of not less than 100 mm. The epitaxial layer has a thickness of not less than 10 μm. The epitaxial layer has a carrier concentration of not less than 1×10¹⁴ cm⁻³ and not more than 1×10¹⁶ cm⁻³. A ratio of a standard deviation of the carrier concentration in a plane of the epitaxial layer to an average value of the carrier concentration in the plane is not more than 10%. The epitaxial layer has a main surface. The main surface has an arithmetic mean roughness Sa of not more than 0.3 nm. An area density of pits originated from a threading screw dislocation is not more than 1000 cm⁻². Each of the pits has a maximum depth of not less than 8 nm.

### TECHNICAL FIELD

The present disclosure relates to a silicon carbide epitaxial substrate.

### BACKGROUND ART

Japanese Patent Laying-Open No. 2014-17439 (Patent Document 1) discloses a CVD (Chemical Vapor Deposition) device that can be used for epitaxial growth of silicon carbide.

### CITATION LIST

### Patent Document

PTD 1: Japanese Patent Laying-Open No. 2014-17439

### SUMMARY OF INVENTION

A silicon carbide epitaxial substrate of the present disclosure includes: a silicon carbide single crystal substrate; and an epitaxial layer on the silicon carbide single crystal substrate. The silicon carbide single crystal substrate has a diameter of not less than 100 mm. The epitaxial layer has a thickness of not less than 10 μm. The epitaxial layer has a carrier concentration of not less than 1×10¹⁴ cm⁻³ and not more than 1×10¹⁶ cm⁻³. A ratio of a standard deviation of the carrier concentration in a plane of the epitaxial layer to an average value of the carrier concentration in the plane is not more than 10%. The epitaxial layer has a main surface. The main surface has an arithmetic mean roughness Sa of not more than 0.3 nm in three-dimensional surface roughness measurement. An area density of pits originated from a threading screw dislocation is not more than 1000 cm⁻² in the main surface. Each of the pits has a maximum depth of not less than 8 nm from the main surface.

### BRIEF DESCRIPTION OF DRAWINGS

FIG. 1 is a schematic view illustrating measurement points for carrier concentration.

FIG. 2 is a schematic cross sectional view showing a configuration of a silicon carbide epitaxial substrate in the present disclosure.

FIG. 3 is a schematic conceptual view showing a first example of a planar shape of a pit.

FIG. 4 is a schematic conceptual view showing a second example of the planar shape of the pit.

FIG. 5 is a schematic conceptual view showing a third example of the planar shape of the pit.

FIG. 6 is a flowchart schematically showing a method for manufacturing the silicon carbide epitaxial substrate in the present disclosure.

FIG. 7 is a schematic side perspective view of a CVD apparatus.

FIG. 8 is a schematic cross sectional view along a VIII-VIII line of FIG. 7.

FIG. 9 is a schematic plan view showing a configuration around a susceptor.

FIG. 10 is a graph showing a first example of distribution of a nitrogen concentration in a diameter direction of an epitaxial layer.

FIG. 11 is a schematic cross sectional view showing the configuration around the susceptor.

FIG. 12 is a graph showing a second example of the distribution of the nitrogen concentration in the diameter direction of the epitaxial layer.

### DESCRIPTION OF EMBODIMENTS

### Description of Embodiments of the Present Disclosure

### First Embodiment

First, a first embodiment of the present disclosure is listed and described. [1] A silicon carbide epitaxial substrate of the present disclosure includes: a silicon carbide single crystal substrate; and an epitaxial layer on the silicon carbide single crystal substrate. The silicon carbide single crystal substrate has a diameter of not less than 100 mm. The epitaxial layer has a thickness of not less than 10 μm. The epitaxial layer has a carrier concentration of not less than 1×10¹⁴ cm⁻³ and not more than 1×10¹⁶ cm⁻³. A ratio of a standard deviation of the carrier concentration in a plane of the epitaxial layer to an average value of the carrier concentration in the plane is not more than 10%. The epitaxial layer has a main surface. The main surface has an arithmetic mean roughness Sa of not more than 0.3 nm in three-dimensional surface roughness measurement. An area density of pits originated from a threading screw dislocation is not more than 1000 cm⁻² in the main surface. Each of the pits has a maximum depth of not less than 8 nm from the main surface.

The silicon carbide epitaxial substrate of the present disclosure is a substrate having both in-plane uniformity of the carrier concentration in the epitaxial layer and the surface property of the epitaxial layer. In other words, in the epitaxial substrate of the present disclosure, the in-plane uniformity of the carrier concentration is high, the surface roughness of the epitaxial layer is small, and an amount of deep pits is reduced in the surface of the epitaxial layer.

In [1], the ratio (σ/ave) of the standard deviation (σ) of the carrier concentration in the plane to the average value (ave) of the carrier concentration in the plane represents the in-plane uniformity of the carrier concentration. As the ratio is lower, the in-plane uniformity of the carrier concentration can be evaluated to be higher. The carrier concentration represents an effective carrier concentration measured by a mercury probe type C-V measurement device. It is assumed that an area of the probe is 0.01 cm². It is assumed that the average value and standard deviation of the carrier concentration are determined based on results of measurements at 9 points in the plane. The 9 points are set in the form of a cross in the plane.

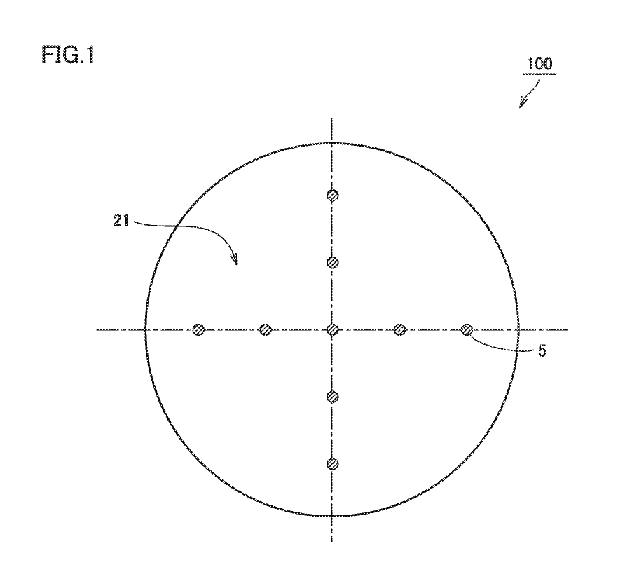

FIG. 1 is a schematic view illustrating the measurement locations for the carrier concentration. As shown in FIG. 1, in silicon carbide epitaxial substrate 100, the intersection of the cross is one of measurement points 5 near the center of silicon carbide epitaxial substrate 100. Measurement points 5 are located at a substantially equal interval.

In [1], arithmetic mean roughness Sa is a three-dimensional surface property parameter defined in International Standard ISO25178. Arithmetic mean roughness Sa is a roughness obtained by expanding arithmetic mean roughness Ra to a plane. Arithmetic mean roughness Sa can be measured using a white light interferometric microscope or the like, for example. For the measurement, it is assumed that an area to be measured is a 255-am square.

In [1], each of the pits is a microscopic defect formed in the surface of the epitaxial layer in the form of a groove. It is considered that the pits are originated from threading screw dislocations, threading edge dislocations, and threading composite dislocations in the epitaxial layer. In the present specification, a threading composite dislocation including a screw dislocation component is also regarded as a threading screw dislocation.

A pit originated from a threading screw dislocation is likely to be deep. This is presumably because strain around the dislocation is relatively large. The present inventor found a manufacturing method by which the depth of a pit originated from a threading screw dislocation can be shallow. Specifically, according to the manufacturing method of the present disclosure, the area density of the pits originated from the threading screw dislocations and having a maximum depth of not less than 8 nm from the main surface of the epitaxial layer can be suppressed to 1000 cm⁻². Moreover, according to the manufacturing method of the present disclosure, arithmetic mean roughness Sa can also be not more than 0.3 nm in the surface of the epitaxial layer. Details of the manufacturing method of the present disclosure will be described later.

Whether or not a pit is originated from a threading screw dislocation is checked through an etch pit method or an X-ray topography method. When the epitaxial layer is formed at the (0001) plane side of the silicon carbide single crystal substrate, the etch pit method is used. According to the etch pit method, for example, the pit originated from the threading screw dislocation can be determined as follows. It should be noted that an etching condition herein is just exemplary, and can be changed in accordance with a thickness of the epitaxial layer, a doping concentration, and the like, for example. The condition below assumes a case where the thickness of the epitaxial layer is about 10 μm to 50 μm.

For the etching, molten potassium hydroxide (KOH) is used. The temperature of the molten KOH is set at about 500° C. to 550° C. Etching time is set at about 5 to 10 minutes. After the etching, the surface of the epitaxial layer is observed using a Nomarski differential-interference microscope. A pit originated from a threading screw dislocation forms a larger etch pit than that by a pit originated from a threading edge dislocation. For example, the etch pit originated from the threading screw dislocation has a hexagonal planar shape, and the length of a diagonal line of the hexagon is typically about 30 μm to 50 μm. For example, the etch pit originated from the threading edge dislocation has a hexagonal planar shape and is smaller than the etch pit originated from the threading screw dislocation. In the etch pit originated from the threading edge dislocation, the length of a diagonal line of the hexagon is typically about 15 μm to 20 μm.

When the epitaxial layer is formed at the (000-1) plane side of the silicon carbide single crystal substrate, the X-ray topography method is used. When the thickness of the epitaxial layer is about 10 μm to 50 μm, a diffraction vector g may be set as g=11-28, and a penetration length may be set at about 20 μm. The threading screw dislocation is observed in a stronger contrast than the threading edge dislocation.

The maximum depth of the pit from the main surface is measured using an AFM (Atomic Force Microscope). The AFM as employed herein may be “Dimension 300” provided by Veeco or the like, for example. For a cantilever of the AFM, “NCHV-10V” provided by Bruker or the like is suitable. For the measurement, each condition in the AFM is set as follows. A measurement mode is set at a tapping mode. A measurement region in the tapping mode is set to be a 5-μm square. For sampling in the tapping mode, a scanning rate in the measurement region is set at 5 seconds per cycle, the number of scan lines is set at 512, and 512 measurement points are set for one scan line. Moreover, controlled displacement for the cantilever was set at 15.50 nm.

The area density of the pits each having a maximum depth of not less than 8 nm from the main surface is measured using both the above-described AFM measurement and a defect inspection device including a confocal differential interference microscope. As the defect inspection device including the confocal differential interference microscope, WASAVI series “SICA 6X” provided by Lasertec or the like can be used. A magnification of objective lens is set at ×10.

By associating the depth data in the AFM measurement with the pit image in the confocal microscope measurement, the shape of the pit having a maximum depth of not less than 8 nm is defined. By analyzing the entire surface of the epitaxial layer, pits satisfying the definition are detected. By dividing the number of the detected pits by the area of the surface of the epitaxial layer, the area density of the pits can be calculated. It is assumed that the entire surface in this measurement does not normally include a region not used for the semiconductor device. The region not used for the semiconductor device is a region of 3 mm from the edge of the substrate, for example.

[2] The area density of the pits may be not more than 100 cm⁻².

[3] The area density of the pits may be not more than 10 cm⁻².

[4] The area density of the pits may be not more than 1 cm⁻².

[5] The silicon carbide single crystal substrate may have a diameter of not less than 150 mm.

[6] The silicon carbide single crystal substrate may have a diameter of not less than 200 mm.

[7] The ratio of the standard deviation of the carrier concentration in the plane of the epitaxial layer to the average value of the carrier concentration in the plane may be not more than 5%.

[8] Each of the pits may have a maximum depth of not less than 20 nm from the main surface.

[9] Each of the pits may have a planar shape including a first width and a second width, the first width extending in a first direction, the second width extending in a second direction perpendicular to the first direction. In this case, the first width is twice or more as large as the second width.

[10] The silicon carbide epitaxial substrate of the present disclosure may be configured as follows.

That is, the silicon carbide epitaxial substrate includes: a silicon carbide single crystal substrate; and an epitaxial layer on the silicon carbide single crystal substrate. The silicon carbide single crystal substrate has a diameter of not less than 100 mm. The epitaxial layer has a thickness of not less than 10 μm. The epitaxial layer has a carrier concentration of not less than 1×10¹⁴ cm⁻³ and not more than 1×10¹⁶ cm⁻³. A ratio of a standard deviation of the carrier concentration in a plane of the epitaxial layer to an average value of the carrier concentration in the plane is not more than 10%. The epitaxial layer has a main surface. The main surface has an arithmetic mean roughness Sa of not more than 0.3 nm in three-dimensional surface roughness measurement. An area density of pits originated from a threading screw dislocation is not more than 1000 cm⁻² in the main surface. Each of the pits has a planar shape including a first width and a second width, the first width extending in a first direction, the second width extending in a second direction perpendicular to the first direction. The first width is twice or more as large as the second width. Each of the pits has a maximum depth of not less than 20 nm from the main surface.

### Details of First Embodiment

Hereinafter, details of the embodiment of the present disclosure will be described. However, the embodiment of the present disclosure is not limited to the description below. In the description below, the same or corresponding elements are given the same reference characters and are not described repeatedly. Regarding crystallographic denotations, an individual orientation is represented by [ ], a group orientation is represented by < >, and an individual plane is represented by ( ), and a group plane is represented by { }. Normally, a plane having a negative crystallographic index is indicated by putting “-” (bar) above a numeral. However, in the present specification, for ease of description, the negative crystallographic index is indicated by putting a negative sign before the numeral.

[Silicon Carbide Epitaxial Substrate]

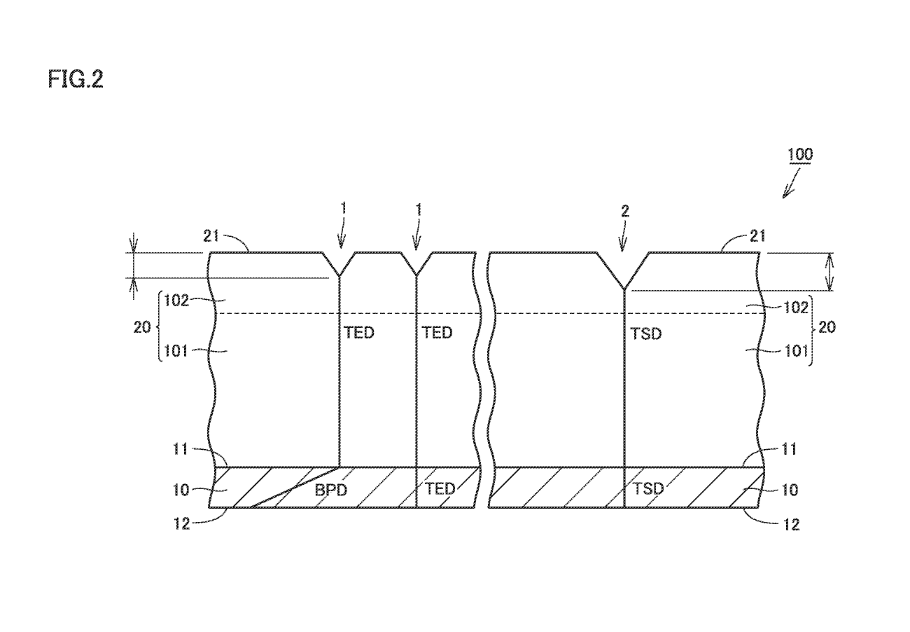

FIG. 2 is a schematic cross sectional view showing an exemplary configuration of a silicon carbide epitaxial substrate in the present disclosure. As shown in FIG. 2, silicon carbide epitaxial substrate 100 includes a silicon carbide single crystal substrate 10, and an epitaxial layer 20 on silicon carbide single crystal substrate 10.

[Silicon Carbide Single Crystal Substrate]

The silicon carbide single crystal substrate is composed of a silicon carbide single crystal. The silicon carbide single crystal may have a polytype of 4H-SiC, for example. 4H-SiC tends to be more excellent than other polytypes in terms of electron mobility, dielectric strength, and the like. The silicon carbide single crystal substrate may have n type conductivity, for example.

The silicon carbide single crystal substrate has a diameter of not less than 100 mm. The diameter may be not less than 150 mm, not less than 200 mm, or not less than 250 mm. The upper limit of the diameter is not particularly limited. The upper limit of the diameter may be 300 mm, for example. The silicon carbide single crystal substrate may have a thickness of about 10 Lm to 5 mm, for example. The thickness of the silicon carbide single crystal substrate is preferably not less than 250 μm and not more than 650 μm.

The silicon carbide single crystal substrate includes a first main surface 11 and a second main surface 12 opposite to first main surface 11. First main surface 11 is in contact with epitaxial layer 20. The first main surface may correspond to a (0001) plane or a (000-1) plane. Alternatively, the first main surface may correspond to a plane inclined by not less than 1° and not more than 8° relative to the (0001) plane or (000-1) plane. A direction in which the first main surface is inclined may be, for example, a <11-20> direction. The angle in which the first main surface is inclined relative to the predetermined crystal plane is also referred to as “off angle”. The off angle may be not less than 2° or not less than 3°. The off angle may be not more than 70, not more than 6°, or not more than 5°.

[Epitaxial Layer]

Epitaxial layer 20 is a homoepitaxial layer formed on first main surface 11. Epitaxial layer 20 is on first main surface 11. Epitaxial layer 20 has a main surface 21 opposite to an interface with silicon carbide single crystal substrate 10.

The epitaxial layer has a thickness of not less than 10 μm. The thickness of the epitaxial layer may be not less than 15 μm, not less than 30 μm, or not less than 50 μm. The upper limit of the thickness of the epitaxial layer is not particularly limited. The upper limit of the thickness of the epitaxial layer may be 200 μm, 150 μm, or 100 μm, for example.

[In-Plane Uniformity of Carrier Concentration]

The epitaxial layer contains nitrogen as a dopant. In the epitaxial layer, the average value of the carrier concentration is not less than 1×10¹⁴ cm⁻³ and not more than 1×10¹⁶ cm⁻³. The average value of the carrier concentration may be not less than 5×10¹⁴ cm⁻³ or not less than 1×10¹⁵ cm⁻³. Moreover, the average value of the carrier concentration may be not more than 8×10¹⁵ cm⁻³ or not more than 5×10¹⁵ cm⁻³.

In the epitaxial layer, the in-plane uniformity (σ/ave) of the carrier concentration is not more than 10%. An in-plane uniformity having a smaller value is more preferable, and the in-plane uniformity is ideally zero. The in-plane uniformity may be not more than 5%, not more than 3%, or not more than 1%.

[Arithmetic Surface Roughness Sa]

The main surface has an arithmetic mean roughness Sa of not more than 0.3 nm in three-dimensional surface roughness measurement. As arithmetic mean roughness Sa is smaller, it can be expected to improve reliability of a semiconductor device more. Arithmetic mean roughness Sa may be not more than 0.2 nm or not more than 0.15 nm.

[Pit]

In main surface 21 of the epitaxial layer, there are “shallow pits 1” each having a maximum depth of less than 8 nm, and “deep pits 2” each having a maximum depth of not less than 8 nm. These pits may be originated from threading screw dislocations (TSD), threading edge dislocations (TED), and the like in the epitaxial layer.

In the main surface of the epitaxial layer of the present disclosure, the area density of pits originated from threading screw dislocations and each having a maximum depth of not less than 8 nm is not more than 1000 cm⁻². A smaller area density of pits is more desirable. The area density of the pits may be not more than 100 cm⁻², not more than 10 cm⁻², or not more than 1 cm⁻². The main surface of the epitaxial layer may include pits originated from threading edge dislocations and each having a maximum depth of less than 8 nm.

In the surface of the epitaxial layer, the area density of the pits originated from the threading screw dislocations and each having a maximum depth of not less than 20 nm may be not more than 1000 cm⁻². The pits each having a maximum depth of not less than 20 nm can be detected based on the shape definition in the above-described defect inspection device. The area density of the pits originated from the threading screw dislocations and each having a maximum depth of not less than 20 nm may be not more than 100 cm⁻², not more than 10 cm⁻², or not more than 1 cm⁻².

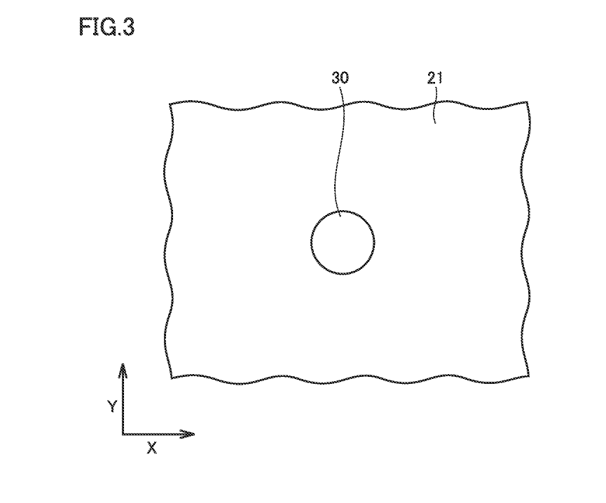

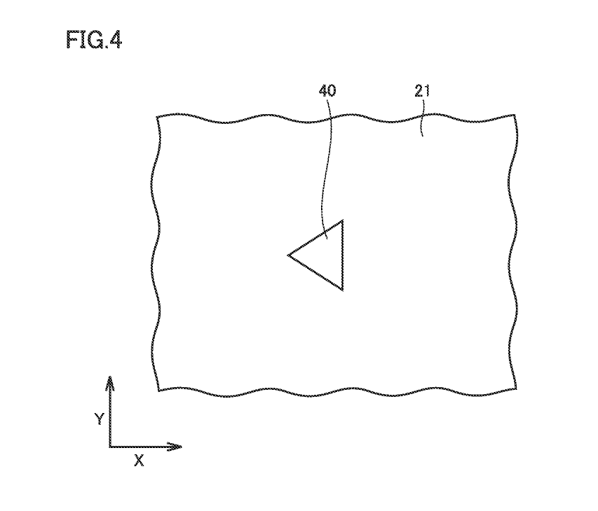

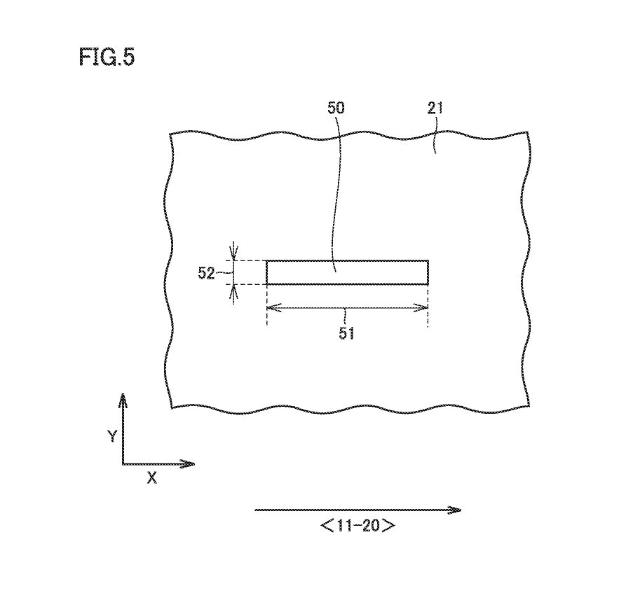

FIG. 3 to FIG. 5 are schematic views each showing an exemplary planar shape of a pit. The planar shape of the pit of the present disclosure may be a circular shape such as a circular pit 30 shown in FIG. 3, a triangular shape such as a triangular pit 40 shown in FIG. 4, or a bar-like shape such as a bar-like pit 50 shown in FIG. 5.

Bar-like pit 50 may include: a first width 51 extending in a first direction; and a second width 52 extending in a second direction perpendicular to the first direction. In FIG. 5, the first direction represents the X-axis direction and the second direction represents the Y-axis direction. In this case, first width 51 is twice or more as large as second width 52. First width 51 may be 5 times or more as large as second width 52. The first width may be, for example, not less than 5 μm or not less than 25 μm. The first width may be, for example, not more than 50 μm or not more than 35 μm. The second width may be, for example, not less than 1 μm or not less than 2 μm. The second width may be, for example, not more than 5 μm or not more than 4 μm. The first direction may be, for example, a <11-20> direction or a <01-10> direction. According to the manufacturing method in the present disclosure, it is also expected to reduce such bar-like pits.

[Method for Manufacturing Silicon Carbide Epitaxial Substrate]

The silicon carbide epitaxial substrate of the present disclosure can be manufactured using the following manufacturing method. It can be expected that the manufacturing method provides an effect of attaining shallow depths of pits originated from threading screw dislocations. Further, the in-plane uniformity of the carrier concentration can be improved in combination with a configuration of a CVD apparatus illustrated in a below-mentioned second embodiment or the like.

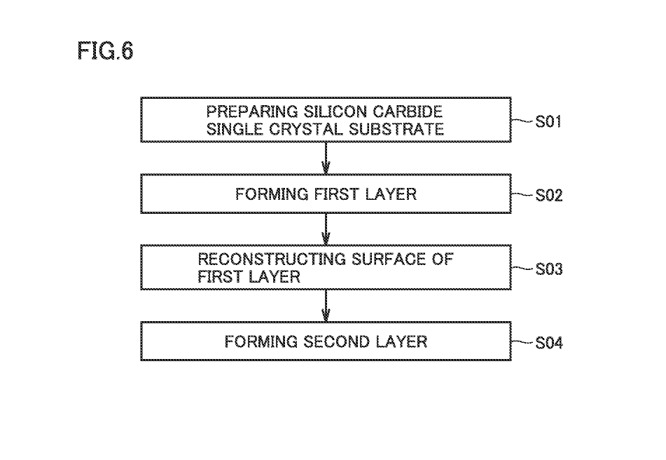

FIG. 6 is a flowchart schematically showing a method for manufacturing the silicon carbide epitaxial substrate in the present disclosure. As shown in FIG. 6, the manufacturing method of the present disclosure includes: a step (S01) of preparing a silicon carbide single crystal substrate; a step (S02) of forming a first layer on the silicon carbide single crystal substrate; a step (S03) of reconstructing a surface of the first layer; and a step (S04) of forming a second layer.

1. Step (S01) of Preparing Silicon Carbide Single Crystal Substrate

In this step (S01), a 4H type silicon carbide ingot (not shown) grown using, for example, a sublimation-recrystallization method is sliced into a predetermined thickness. Accordingly, a silicon carbide single crystal substrate is prepared.

2. Step (S02) of Forming First Layer

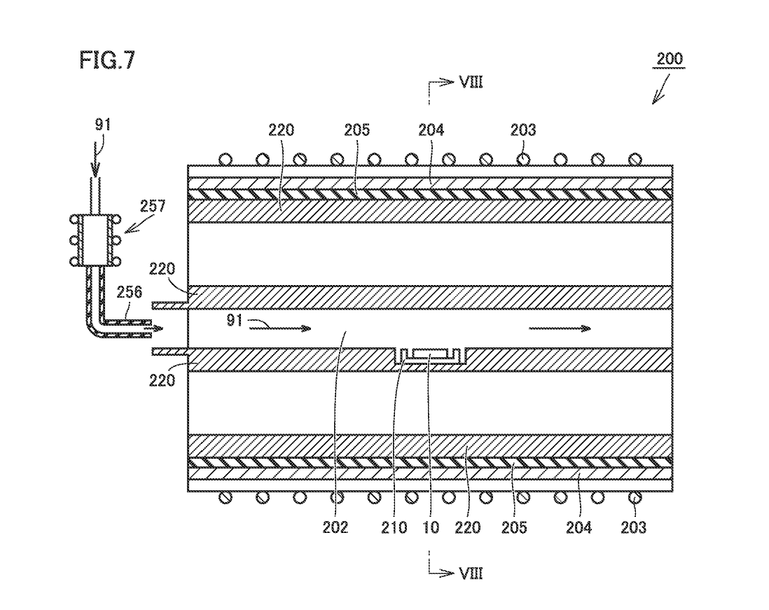

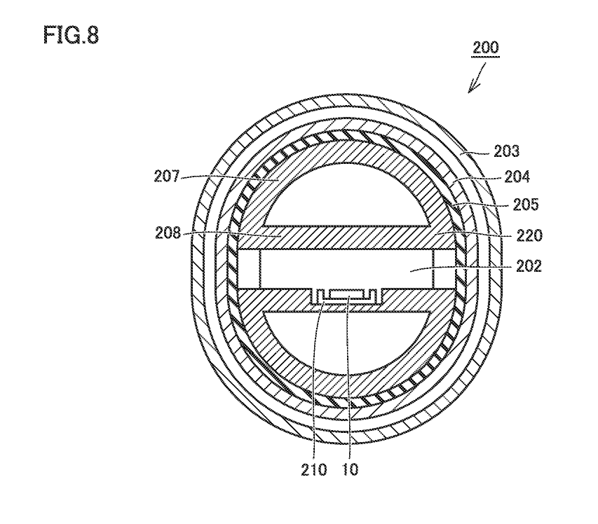

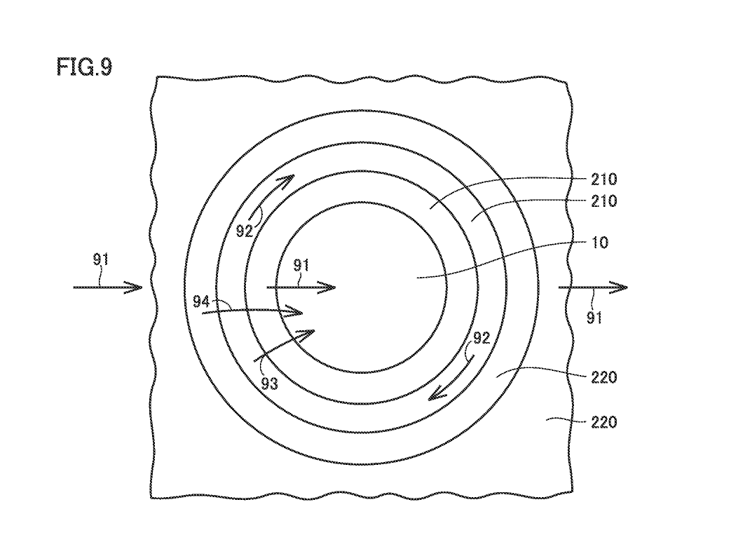

Subsequent steps are performed in a CVD apparatus shown in FIG. 7 and FIG. 8. FIG. 7 is a schematic side perspective view of the CVD apparatus. FIG. 8 is a schematic cross sectional view taken along a VIII-VIII line of FIG. 7. As shown in FIG. 8, CVD apparatus 200 includes heating elements 220, a heat insulator 205, a quartz tube 204, and an induction heating coil 203. Each of heating elements 220 is composed of graphite, for example. As shown in FIG. 9, heating element 220 has a semi-cylindrical hollow structure including a curved portion 207 and a flat portion 208. Two heating elements 220 are provided and disposed such that their respective flat portions 208 face each other. A space surrounded by these flat portions 208 is a channel 202. In channel 202, a susceptor 210 is disposed on which the silicon carbide single crystal substrate can be held. The susceptor is rotatable. The structure of the CVD apparatus will be described in detail in the second embodiment.

Silicon carbide single crystal substrate 10 is placed on susceptor 210 with first main surface 11 facing upward. In this step, a source material gas having a C/Si ratio of less than 1 is used to epitaxially grow a first layer 101 (see FIG. 2) on first main surface 11. First, after gas replacement in channel 2, a pressure in channel 202 is adjusted to a predetermined pressure such as 60 mbar to 100 mbar (6 kPa to 10 kPa) while letting a carrier gas to flow. The carrier gas may be, for example, hydrogen (H₂) gas, argon (Ar) gas, helium (He) gas, or the like. The flow rate of the carrier gas may be about 50 slm to 200 slm, for example. The unit for flow rate as used herein, i.e., “slm (Standard Liter per Minute)” represents “L/min” in a standard condition (0° C. and 101.3 kPa).

Next, a predetermined alternating current is supplied to induction heating coil 203, thereby inductively heating heating elements 220. Accordingly, each of channel 202 and susceptor 210 is heated to a predetermined reaction temperature. On this occasion, the susceptor is heated to about 1500° C. to 1750° C., for example.

Next, a source material gas is supplied. The source material gas includes a Si source gas and a C source gas. Examples of the Si source gas includes silane (SiH₄) gas, disilane (Si₂H₆) gas, dichlorosilane (SiH₂Cl₂) gas, trichlorosilane (SiHCl₃) gas, silicon tetrachloride (SiCl₄) gas, and the like. That is, the Si source gas may be at least one selected from a group consisting of silane gas, disilane gas, dichlorosilane gas, trichlorosilane gas and silicon tetrachloride gas.

Examples of the C source gas include methane (CH₄) gas, ethane (C₂H₆) gas, propane (C₃H₈) gas, acetylene (C₂H₂) gas, and the like. That is, the C source gas may be at least one selected from a group consisting of methane gas, ethane gas, propane gas, and acetylene gas.

The source material gas may include a dopant gas. Examples of the dopant gas include nitrogen gas, ammonia gas, and the like.

The source material gas in the step of forming the first layer may be a mixed gas of silane gas and propane gas, for example. In the step of forming the first layer, the C/Si ratio of the source material gas is adjusted to less than 1. For example, the C/Si ratio may be not less than 0.5, not less than 0.6, or not less than 0.7 as long as the C/Si ratio is less than 1. Moreover, for example, the C/Si ratio may be not more than 0.95, not more than 0.9, or not more than 0.8. The flow rate of the silane gas and the flow rate of the propane gas may be adjusted appropriately in a range of about 10 to 100 sccm to achieve a desired C/Si ratio, for example. The unit for flow rate as used herein, i.e., “sccm (Standard Cubic Centimeter per Minute)” represents “mL/min” in a standard condition (0° C. and 101.3 kPa).

A film formation rate in the step of forming the first layer may be about not less than 3 μm/h and not more than 30 μm/h, for example. The first layer has a thickness of not less than 0.1 μm and not more than 150 μm, for example. The thickness of the first layer may be not less than 0.2 μm, not less than 1 μm, not less than 10 μm, or not less than 15 μm. Moreover, the thickness of the first layer may be not more than 100 μm, not more than 75 μm, or not more than 50 μm.

3. Step (S03) of Reconstructing Surface of First Layer

Next, the step of reconstructing a surface of the first layer is performed. The step of reconstructing the surface may be performed continuous to the step of forming the first layer. Alternatively, a predetermined halt time may be provided between the step of forming the first layer and the step of reconstructing the surface. In the step of reconstructing the surface, the temperature of the susceptor may be increased by about 10° C. to 30° C.

In the step of reconstructing the surface, a mixed gas including a source material gas having a C/Si ratio of less than 1 and hydrogen gas is used. The C/Si ratio of the source material gas may be lower than the C/Si ratio in the step of forming the first layer. The C/Si ratio may be not less than 0.5, not less than 0.6, or not less than 0.7 as long as the C/Si ratio is less than 1. Moreover, for example, the C/Si ratio may be not more than 0.95, not more than 0.9, or not more than 0.8.

In the step of reconstructing the surface, there may be used a source material gas different from the source material gas used in each of the step of forming the first layer and the below-described step of forming the second layer. In this way, it is expected to increase an effect of suppressing formation of deep pits. For example, it is considered to configure such that in each of the step of forming the first layer and the below-described step of forming the second layer, silane gas and propane gas are used, whereas in the step of reconstructing the surface, dichlorosilane and acetylene are used.

In the step of reconstructing the surface, the ratio of the flow rate of the source material gas to the flow rate of the hydrogen gas may be decreased as compared with those in the step of forming the first layer and the below-described step of forming the second layer. Accordingly, it is expected to increase the effect of suppressing formation of deep pits.

The flow rate of the hydrogen gas in the mixed gas may be about not less than 100 slm and not more than 150 slm, for example. The flow rate of the hydrogen gas may be about 120 slm, for example. The flow rate of the Si source gas in the mixed gas may be not less than 1 sccm and not more than 5 sccm, for example. The lower limit of the flow rate of the Si source gas may be 2 sccm. The upper limit of the flow rate of the Si source gas may be 4 sccm. The flow rate of the C source gas in the mixed gas may be not less than 0.3 sccm and not more than 1.6 sccm, for example. The lower limit of the flow rate of the C source gas may be 0.5 sccm or 0.7 sccm. The upper limit of the C source gas may be 1.4 sccm or 1.2 sccm.

In the step of reconstructing the surface, it is desirable to adjust various conditions such that etching by the hydrogen gas is comparable to epitaxial growth by the source material gas. For example, it is considered to adjust the flow rate of the hydrogen gas and the flow rate of the source material gas to attain a film formation rate of about 0±0.5 μm/h. The film formation rate may be adjusted to about 0±0.4 μm/h, may be adjusted to about 0±0.3 μm/h, about 0±0.2 μm/h, or about 0±0.1 μm/h. Accordingly, it is expected to increase the effect of suppressing formation of deep pits.

A treatment time in the step of reconstructing the surface is about not less than 30 minutes and not more than 10 hours, for example. The treatment time may be not more than 8 hours, not more than 6 hours, not more than 4 hours, or not more than 2 hours.

4. Step (S04) of Forming Second Layer

After reconstructing the surface of the first layer, the step of forming the second layer on this surface is performed. Second layer 102 (see FIG. 2) is formed using a source material gas having a C/Si ratio of not less than 1. For example, the C/Si ratio may be not less than 1.05, not less than 1.1, not less than 1.2, not less than 1.3, or not less than 1.4 as long as the C/Si ratio is not less than 1. Moreover, the C/Si ratio may be not more than 2.0, not more than 1.8, or not more than 1.6.

The source material gas in the step of forming the second layer may be the same as or different from the source material gas used in the step of forming the first layer. The source material gas may be silane gas and propane gas, for example. The flow rate of the silane gas and the flow rate of the propane gas may be adjusted appropriately in a range of about 10 to 100 sccm to achieve a desired C/Si ratio, for example. The flow rate of the carrier gas may be about 50 slm to 200 slm, for example.

The film formation rate in the step of forming the second layer may be about not less than 5 μm/h and not more than 100 μm/h, for example. The second layer has a thickness of not less than 1 μm and not more than 150 μm, for example. Moreover, the thickness of the second layer may be not less than 5 μm, not less than 10 μm, or not less than 15 μm. Moreover, the thickness of the second layer may be not more than 100 μm, not more than 75 μm, or not more than 50 μm.

The thickness of second layer 102 may be the same as or different from the thickness of first layer 101. Second layer 102 may be thinner than first layer 101. For example, the ratio of the thickness of second layer 102 to the thickness of first layer 101 may be about not less than 0.01 and not more than 0.9. Here, the ratio of the thicknesses represents a value obtained by dividing the thickness of the second layer by the thickness of the first layer having been through the step of reconstructing the surface. The ratio of the thicknesses may be not more than 0.8, not more than 0.7, not more than 0.6, not more than 0.5, not more than 0.4, not more than 0.3, not more than 0.2, or not more than 0.1. Accordingly, it is expected to increase the effect of suppressing formation of deep pits.

In this way, as shown in FIG. 2, epitaxial layer 20 including first layer 101 and second layer 102 is formed. In epitaxial layer 20, the first layer and the second layer may be incorporated completely such that they cannot be distinguished from each other. In epitaxial layer 20, generation of the deep pits originated from the threading screw dislocations is suppressed, thus resulting in a low arithmetic mean roughness Sa.

### Second Embodiment

### Overview of Second Embodiment

An overview of the second embodiment of the present disclosure is listed and described.

[1] A silicon carbide epitaxial substrate includes: a silicon carbide single crystal substrate; and an epitaxial layer formed on the silicon carbide single crystal substrate and having a main surface. In the main surface, pits each having a maximum depth of not less than 8 nm from the main surface are formed, and an area density of the pits in the main surface is not more than 8 cm⁻². A ratio of a standard deviation of a nitrogen concentration in a plane of the epitaxial layer to an average value of the nitrogen concentration in the plane is not more than 8%.

In the silicon carbide epitaxial substrate, as an index for the in-plane uniformity of the nitrogen concentration (carrier concentration), the ratio of the standard deviation (σ) of the nitrogen concentration in the plane of the epitaxial layer to the average value (ave) of the nitrogen concentration in the plane is employed, i.e., a percentage of a value (σ/ave) obtained by dividing the standard deviation (σ) by the average value (ave) is employed. It can be said that as the value of “σ/ave” is smaller, the in-plane uniformity of the nitrogen concentration is higher. According to the research by the present inventor, performance variation of semiconductor devices can be sufficiently reduced when the percentage of “σ/ave” is not more than 8%.

The epitaxial layer having such a high in-plane uniformity of nitrogen concentration can be formed, for example, in the following manner: when growing the epitaxial layer by CVD, a ratio (hereinafter, referred to as “C/Si ratio”) of the number of atoms of carbon (C) to the number of atoms of silicon (Si) in the source material gas is adjusted to be high to reduce an amount of nitrogen to be included therein. However, in the epitaxial layer grown with the C/Si ratio being set to be high, the area density of the pits tends to be increased. According to a research by the present inventor, among these pits, pits each having a maximum depth of not less than 8 nm from the main surface of the epitaxial layer particularly affect long-term reliability of semiconductor devices. That is, when an oxide film is formed on the epitaxial layer, the thickness of the oxide film is varied around the deep pits. Also, it is considered that an electric field is likely to be concentrated in the oxide film at its portion having a thin thickness, thus resulting in a decreased life of the oxide film.

Hence, in the above silicon carbide epitaxial substrate, the area density of the pits each having a maximum depth of not less than 8 nm from the main surface is limited to not more than 8 cm⁻². Accordingly, long-term reliability of semiconductor devices can be improved.

[2] The main surface preferably has an arithmetic mean roughness Sa of not more than 0.5 nm in three-dimensional surface roughness measurement. Accordingly, long-term reliability of semiconductor devices can be improved.

[3] The nitrogen concentration may be not more than 2×10¹⁶ cm⁻³. Accordingly, breakdown voltage performances of the semiconductor devices can be improved.

However, if the nitrogen concentration is set at a low concentration to be not more than 2×10¹⁶ cm⁻³, an influence of background over the in-plane uniformity may become large. The background refers to nitrogen originated from nitrogen other than nitrogen introduced intentionally. In order to reduce the background concentration, it is considered to use a member having a low nitrogen concentration for a member around the silicon carbide single crystal substrate in a CVD apparatus, for example.

[4] The silicon carbide single crystal substrate preferably has a diameter of not less than 100 mm. This may contribute to reduction of manufacturing cost of semiconductor devices. For example, when growing the epitaxial layer, it is considered to use ammonia (NH₃) as a dopant gas, heat the dopant gas in advance, and supply it to a reaction chamber of the CVD apparatus. Accordingly, even in the case of a substrate having a large diameter of not less than 100 mm, the in-plane uniformity can be controlled to be not more than 8%.

[5] A silicon carbide epitaxial substrate includes: a silicon carbide single crystal substrate having a diameter of not less than 100 mm; and an epitaxial layer formed on the silicon carbide single crystal substrate and having a main surface. The epitaxial layer has a thickness of not less than 5 Lm and not more than 50 μm. In the main surface, pits each having a maximum depth of not less than 8 nm from the main surface are formed, and an area density of the pits in the main surface is not more than 8 cm⁻². The main surface has an arithmetic mean roughness Sa of not more than 0.5 nm in three-dimensional surface roughness measurement. A ratio of a standard deviation of a nitrogen concentration in a plane of the epitaxial layer to an average value of the nitrogen concentration in the plane is not more than 8%. The nitrogen concentration is not more than 2×10¹⁶ cm⁻³.

Accordingly, there can be provided a silicon carbide epitaxial substrate having a high in-plane uniformity of nitrogen concentration and capable of improving long-term reliability of semiconductor devices.

### Details of Second Embodiment

[Silicon Carbide Epitaxial Substrate]

The following describes a configuration of a silicon carbide epitaxial substrate of the second embodiment. As shown in FIG. 2, a silicon carbide epitaxial substrate 100 includes: a silicon carbide single crystal substrate 10; and an epitaxial layer 20 formed on silicon carbide single crystal substrate 10.

[Silicon Carbide Single Crystal Substrate]

The polytype of silicon carbide in silicon carbide single crystal substrate 10 is desirably 4H-SiC because 4H-SiC is more excellent than other polytypes in terms of electron mobility, dielectric strength, and the like. Silicon carbide single crystal substrate 10 preferably has a diameter of not less than 100 mm, more preferably, not less than 150 mm. A larger diameter of silicon carbide single crystal substrate 10 may more contribute to reduction of manufacturing cost of semiconductor devices.

Silicon carbide single crystal substrate 10 has a first main surface 11, on which epitaxial layer 20 is formed. The first main surface, which is a growth surface, preferably corresponds to a plane inclined by not less than 1° and not more than 8° relative to a (0001) plane or (000-1) plane. That is, silicon carbide single crystal substrate 10 preferably has an off angle of not less than 1° and not more than 8°. Such introduction of the off angle into silicon carbide single crystal substrate 10 induces so-called “step-flow growth”, i.e., lateral growth from atomic steps exhibited on the growth surface when growing epitaxial layer 20 by CVD. In this way, the single crystal can be grown to have a polytype transferred from silicon carbide single crystal substrate 10. That is, a different type of polytype can be suppressed from being mixed therein. Here, a direction in which the off angle is provided is desirably the <11-20> direction. The off angle is more preferably not less than 2° and not more than 7°, is particularly preferably not less than 3° and not more than 6°, and is most preferably not less than 3° and not more than 5°.

[Epitaxial Layer]

Epitaxial layer 20 is a silicon carbide single crystal layer epitaxially grown on first main surface 11 serving as the growth surface. Epitaxial layer 20 has a thickness of not less than 5 μm and not more than 50 μm. The lower limit of the thickness of the epitaxial layer may be 10 μm or 15 μm. The upper limit of the thickness of the epitaxial layer may be 40 μm or 30 μm. Epitaxial layer 20 contains nitrogen as a dopant, and has n type conductivity.

In the second embodiment, the area density of deep pits 2 (each having a maximum depth of not less than 8 nm) in main surface 21 is not more than 8 cm⁻². Accordingly, long-term reliability of a semiconductor device manufactured using silicon carbide epitaxial substrate 100 can be improved. A lower area density of the deep pits is more preferable, and the area density is ideally 0 (zero). The area density of the deep pits is more preferably not more than 5 cm⁻², is particularly preferably not more than 1 cm⁻², and is most preferably not more than 0.5 cm⁻².

The main surface preferably has an arithmetic mean roughness Sa of not more than 0.5 nm in three-dimensional surface roughness measurement in order to improve long-term reliability of the semiconductor device. A smaller arithmetic mean roughness Sa is more preferable, and arithmetic mean roughness Sa is ideally zero. Arithmetic mean roughness Sa is more preferably not more than 0.3 nm, and is particularly preferably not more than 0.15 nm.

The in-plane uniformity (percentage of “σ/ave”) of the nitrogen concentration in the epitaxial layer is not more than 8%. Accordingly, performance variation of semiconductor devices manufactured using silicon carbide epitaxial substrate 100 can be reduced. A smaller percentage of “6/ave” is more preferable, and the percentage is ideally zero. The percentage of “σ/ave” is more preferably not more than 6%, and is particularly preferably not more than 4%.

The nitrogen concentration (carrier concentration) of the epitaxial layer is preferably not more than 2×10¹⁶ cm⁻³ in order to improve a breakdown voltage property of the semiconductor device. Conventionally, when the nitrogen concentration is decreased to about not more than 2×10¹⁶ cm⁻³, it is difficult to reduce the in-plane uniformity of the nitrogen concentration to not more than 8%. However, in the present embodiment, by reducing nitrogen background as described below, an in-plane uniformity of not more than 8% can be attained. The nitrogen concentration is more preferably not more than 1.8×10¹⁶ cm⁻³, and is particularly preferably not more than 1.5×10¹⁶ cm⁻³. Further, in consideration of on resistance of the semiconductor device, the nitrogen concentration is preferably not less than 1×10¹⁵ cm⁻³.

Here, the “background concentration of nitrogen” can be measured by growing the epitaxial layer without supplying a dopant gas and by analyzing the nitrogen concentration in the epitaxial layer by SIMS (Secondary Ion Mass Spectrometry).

In the epitaxial layer, the background concentration of the nitrogen is preferably not more than 1×10¹⁵ cm⁻³ because the in-plane uniformity of the nitrogen concentration can be improved. A lower background concentration of nitrogen is more preferable, and the background concentration is more preferably not more than 8×10¹⁴ cm⁻³, and is particularly preferably 5×10¹⁴ cm⁻³.

[CVD Apparatus]

A configuration of the CVD apparatus will be described. According to this configuration, the in-plane uniformity of the carrier concentration can be improved. As shown in FIG. 7 and FIG. 8, CVD apparatus 200 includes heating elements 220, a heat insulator 205, a quartz tube 204, and an induction heating coil 203.

As shown in FIG. 9, two heating elements 220 are provided, and each of heating elements 220 has a hollow semi-cylindrical structure including a curved portion 207 and a flat portion 208. Two flat portions 208 are disposed to face each other. A space surrounded by two flat portions 208 serves as a reaction chamber (channel 202). Channel 202 is provided with a recess, in which a substrate holder (susceptor 210) is provided. Susceptor 210 is capable of holding silicon carbide single crystal substrate 10 and is configured to be rotatable.

Heat insulator 205 is disposed to surround the outer circumference portions of heating elements 220. Channel 202 is thermally insulated by heat insulator 205 from outside of CVD apparatus 200. Quartz tube 204 is disposed to surround the outer circumference portion of heat insulator 205. Induction heating coil 203 is wound along the outer circumference portion of quartz tube 204. In CVD apparatus 200, an alternating current is supplied to induction heating coil 203, thereby inductively heating heating element 220. In this way, a temperature within the channel can be controlled.

FIG. 9 is a schematic plan view showing a configuration around susceptor 210. Second arrows 92 in FIG. 9 represent the rotation direction of susceptor 210. Moreover, first arrows 91 represent the supply direction of source material gas. The source material gas includes a dopant gas. As indicated by first arrows 91, the source material gas flows in one direction. However, since susceptor 210 is rotated, silicon carbide single crystal substrate 10 is substantially uniformly supplied with the source material gas in the rotation direction of susceptor 210. Accordingly, in epitaxial layer 20, the in-plane uniformity of the nitrogen concentration can be improved.

[Configurations of Susceptor and Heating Element]

Each of susceptor 210 and heating element 220 is desirably composed of a material having a low nitrogen concentration in order to reduce the nitrogen background concentration in the epitaxial layer. A third arrow 93 in FIG. 9 represents nitrogen released from susceptor 210, and a fourth arrow 94 represents nitrogen released from heating element 220. As indicated by third arrow 93 and fourth arrow 94, when each of susceptor 210 and heating element 220 contains nitrogen, this nitrogen is supplied to silicon carbide single crystal substrate 10 and the epitaxial layer together with the source material gas, and becomes the nitrogen background.

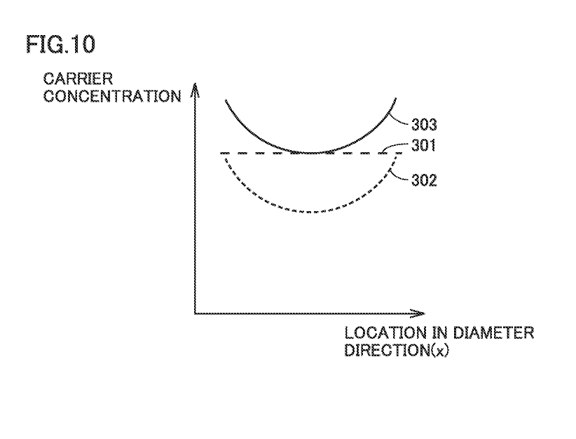

FIG. 10 is a graph showing a first example of distribution of the nitrogen concentration in the diameter direction of the epitaxial layer. In FIG. 10, a dashed line 301 represents distribution of the nitrogen originated from the dopant gas, whereas a dotted line 302 represents distribution of the nitrogen originated from the nitrogen released from susceptor 210 and the like. That is, dotted line 302 indicates the background. In this case, distribution of actual nitrogen is represented by a solid line 303, which is obtained by adding dashed line 301 and dotted line 302. In this way, the in-plane uniformity becomes low due to the influence of the background. Such a tendency becomes notable in the case where the nitrogen concentration of the epitaxial layer is set to be low. The case where the nitrogen concentration is set to be low refers to a case where the nitrogen concentration is set at not more than 2×10¹⁶ cm⁻³, for example.

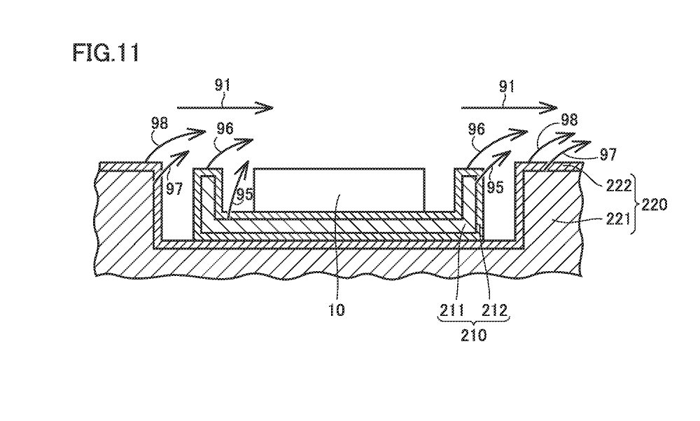

In view of this, in the present embodiment, each of susceptor 210 and heating element 220 is configured to have a low content of nitrogen. FIG. 11 is a schematic cross sectional view showing the configuration around the susceptor. As shown in FIG. 11, susceptor 210 includes a first base member 211 and a first coating portion 212 that covers first base member 211. Moreover, heating element 220 includes a second base member 221 and a second coating portion 222 that covers second base member 221.

Each of first base member 211 and second base member 221 is composed of a carbon material, for example. Each of first base member 211 and second base member 221 preferably has a nitrogen concentration of not more than 10 ppm, and more preferably, not more than 5 ppm. Each of first coating portion 212 and second coating portion 222 is composed of silicon carbide (SiC) or tantalum carbide (TaC), for example. The nitrogen concentration of each of first coating portion 212 and second coating portion 222 is preferably not more than 10 ppm, and is more preferably not more than 5 ppm.

In FIG. 11, fifth arrows 95 represent nitrogen released from first base member 211, and sixth arrows 96 represent nitrogen released from first coating portion 212. Moreover, seventh arrows 97 represent nitrogen released from second base member 221, and eighth arrows 98 represent nitrogen released from second coating portion 222. As described above, by setting the nitrogen concentration of each member to be low, the nitrogen therefrom can be sufficiently reduced. Accordingly, the nitrogen background concentration in the epitaxial layer can be not more than 1×10¹⁵ cm⁻³.

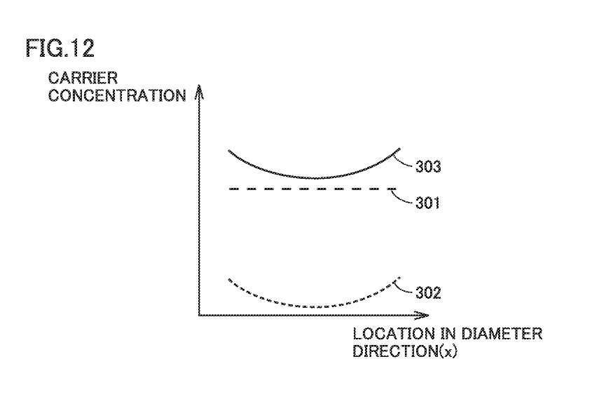

FIG. 12 is a graph showing a second example of distribution of the nitrogen concentration in the diameter direction of the epitaxial layer. In the second example, the members each having a low nitrogen concentration are employed for the susceptor and the like. By sufficiently reducing dotted line 302 indicating the background as shown in FIG. 12, solid line 303 indicating the distribution of the nitrogen concentration in epitaxial layer 20 can be closer to dashed line 301 indicating the ideal distribution.

[Preheating Structure]

As indicated by first arrows 91 in FIG. 7, the source material gas is supplied to the reaction chamber (channel 202) via a pipe 256. The source material gas includes silane (SiH₄) gas, propane (C₃H₈) gas, ammonia (NH₃) gas, and the like. For the carrier gas, hydrogen (H₂) gas is used, for example. The carrier gas may include rare gas such as argon gas, for example. The environment of channel 202 is adjusted such that each in the source material gas is thermally decomposed before reaching silicon carbide single crystal substrate 10.

The ammonia gas serving as the dopant gas in the source material gas is desirably thermally decomposed in advance by sufficiently heating it before supplying the ammonia gas to channel 202 in order to improve the in-plane uniformity of the nitrogen concentration (carrier concentration) in the epitaxial layer. For example, in preheating structure 257 shown in FIG. 7, the ammonia gas can be heated in advance. Preheating structure 257 includes a chamber heated to not less than 1300° C. The ammonia gas is sufficiently thermally decomposed when passing through the inside of preheating structure 257, and is then supplied to channel 202. With such a configuration, the ammonia gas can be thermally decomposed without causing a large turbulence in the flow of the gas. Here, the “chamber” included in preheating structure 257 refers to a space for heating the gas. For example, the “chamber” included in preheating structure 257 broadly encompasses: an elongated pipe to be externally heated; a chamber having an electric heating coil provided therein; and a wide chamber having an inner wall surface provided with a fin or the like.

The temperature of the inner wall surface of preheating structure 257 is more preferably not less than 1350° C. in order to facilitate thermal decomposition of the ammonia gas. Moreover, in consideration of thermal efficiency, the temperature of the inner wall surface of preheating structure 257 is preferably not more than 1600° C.

Preheating structure 257 may be in one piece with channel 202 and may be separated therefrom. Moreover, the gas to be supplied through the inside of preheating structure 257 may be only the ammonia gas or may include a different gas. For example, the whole of the source material gas may be supplied through the inside of preheating structure 257.

### Third Embodiment

### Overview of Third Embodiment

A third embodiment of the present disclosure is listed and described.

[1] An epitaxial wafer (silicon carbide epitaxial substrate) includes a silicon carbide layer (epitaxial layer) having a main surface. In a main surface of the epitaxial layer, pits each having a maximum depth of not less than 8 nm from the main surface are formed. An area density of the pits in the main surface of the epitaxial layer is not more than 1000 cm⁻².

When forming the epitaxial layer on the silicon carbide substrate (silicon carbide single crystal substrate), minute pits may be formed in the main surface of the epitaxial layer. Each of these pits is a depression having a depth of about several nm to about several ten nm, and has a side surface including a {0001} plane. The present inventor found that such a pit is a cause to increase variation in film thickness of an oxide film to serve as a gate insulating film of a silicon carbide semiconductor device.

Specifically, silicon carbide having a 4H type hexagonal crystal structure has a plane orientation dependency of oxidation rate such that oxidation rate differs depending on a plane orientation. Accordingly, the oxidation rate is fastest for a (000-1) plane (C plane), and the oxidation rate is the slowest for a (0001) plane (Si plane). Hence, when forming a gate insulating film (oxide film) for a silicon carbide semiconductor device on the main surface of the epitaxial layer, the thickness of the oxide film is varied due to the plane orientation dependency of oxidation rate. Particularly, since the oxidation rate is the slowest for the side surface of the pit including the (0001) plane, the thickness of the oxide film formed near the side surface of the pit becomes thin locally. Accordingly, in the vicinity of the side surface of the pit, a leak path for current is formed locally, with the result that the insulating property of the oxide film may be deteriorated. In the silicon carbide semiconductor device manufactured using such a silicon carbide epitaxial substrate, the insulating property of the gate insulating film is deteriorated with passage of time due to application of a high electric field. When the insulating property of the gate insulating film is deteriorated, leakage current may be increased, with the result that the breakdown voltage of the silicon carbide semiconductor device is deteriorated with passage of time. In other words, long-term reliability of the silicon carbide semiconductor device is compromised.

According to the description above, the variation in the film thickness of the oxide film becomes larger as the depth of the pit becomes deeper. Particularly, when the maximum depth (corresponding to the maximum depth of the entire pit) from the main surface of the epitaxial layer becomes not less than 8 nm, the variation in the film thickness of the oxide film is increased remarkably, thus affecting the long-term reliability of the silicon carbide semiconductor device. On the other hand, when the maximum depth of the pit from the main surface is less than 8 nm, the variation in the film thickness of the oxide film hardly affects the long-term reliability of the silicon carbide semiconductor device. Hence, by reducing the area density of the pits each having a maximum depth of not less than 8 nm from the main surface, the variation in the film thickness of the oxide film can be reduced, thus improving the long-term reliability of the silicon carbide semiconductor device.

Further, the inventor diligently conducted a research as to reducing the area density of the pits in the main surface to such an extent that the influence of the variation in the thickness of the oxide film over the long-term reliability is reduced.

As a result, it was found that the influence over the long-term reliability of the silicon carbide semiconductor device can be reduced by reducing the area density of the pits in the main surface to at least not more than 1000 cm⁻². The area density of the pits in the main surface of the epitaxial layer is preferably not more than 1000 cm⁻², is more preferably not more than 100 cm⁻², and is further preferably not more than 10 cm⁻².

[2] Preferably in [1], a threading screw dislocation density in the epitaxial layer is lower than a threading edge dislocation density in the epitaxial layer.

The pits formed in the main surface of the epitaxial layer are originated from threading dislocations mainly in the epitaxial layer. Specifically, the pits each having a maximum depth of not less than 8 nm from the main surface are originated from threading screw dislocations, whereas the pits each having a maximum depth of less than 8 nm from the main surface are originated from threading edge dislocations. Hence, in order to reduce the area density of the pits, it is effective to reduce the threading screw dislocation density in the epitaxial layer. On the other hand, the threading edge dislocation density in the epitaxial layer is not required to be reduced. Hence, according to the silicon carbide epitaxial substrate including the above epitaxial layer having the threading screw dislocation density lower than the threading edge dislocation density, the area density of the deep pits is reduced. Accordingly, the variation in the film thickness of the oxide film can be reduced.

[3] Preferably in [2], the threading edge dislocation density in the epitaxial layer is not less than 1000 cm⁻². Accordingly, a ratio of the threading screw dislocations in the epitaxial layer is less than a ratio of the threading edge dislocations therein, with the result that the area density of the deep pits is reduced to be not more than 1000 cm². Accordingly, the variation in the film thickness of the oxide film can be reduced.

The threading screw dislocation density and the threading edge dislocation density can be measured by forming etch pits through selective etching and observing the etch pits using an optical microscope, for example. Examples of methods for the selective etching include immersion into a molten salt (molten KOH) of heated potassium hydroxide, and the like. Alternatively, the threading screw dislocation density and the threading edge dislocation density can be measured by observing the main surface of the epitaxial layer using the defect inspection device based on such a fact that the deep pit and the shallow pit are originated from the threading screw dislocation and the threading edge dislocation respectively.

[4] Preferably in [1] to [3], the epitaxial wafer further includes a silicon carbide single crystal substrate having a first main surface on which the epitaxial layer is formed. The first main surface corresponds to a plane having an off angle of not more than 10⁰ relative to the {0001} plane. When such an off substrate having the first main surface inclined relative to the basal plane is used for the silicon carbide single crystal substrate, most of basal plane dislocations in the substrate are transformed into threading edge dislocations during the epitaxial growth. Accordingly, the threading edge dislocation density in the epitaxial layer can be increased. Thus, the threading screw dislocation density in the epitaxial layer is decreased, thereby reducing the area density of the deep pits.

### Details of Third Embodiment

[Configuration of Silicon Carbide Epitaxial Substrate]

As shown in FIG. 2, a silicon carbide epitaxial substrate 100 mainly includes a silicon carbide single crystal substrate 10 and an epitaxial layer 20. Silicon carbide single crystal substrate 10 is composed of a silicon carbide single crystal, for example. The silicon carbide of the silicon carbide single crystal substrate has a hexagonal crystal structure, and has a polytype of 4H type, for example. The silicon carbide single crystal substrate includes an n type impurity, such as nitrogen (N). The silicon carbide single crystal substrate has an impurity concentration of not less than 5.0×10 cm⁻³ and not more than 2.0×10¹⁹ cm⁻³, for example. The silicon carbide single crystal substrate has a diameter of not less than 100 mm (not less than 4 inches), preferably, not less than 150 mm (not less than 6 inches), for example.

Silicon carbide single crystal substrate 10 has a first main surface 11 and a second main surface 12 opposite to first main surface 11. Each of first main surface 11 and second main surface 12 may correspond to a {0001} plane, or a plane having a predetermined off angle (for example, off angle of not more than 10°) relative to the {0001} plane. For example, first main surface 11 may correspond to a (0001) plane (Si plane) or a plane having the above off angle relative to the (0001) plane (Si plane), and second main surface 12 may correspond to a (000-1) plane (C plane) or a plane having the above off angle relative to the (000-1) plane (C plane).

Epitaxial layer 20 is formed on a first main surface 11 of silicon carbide single crystal substrate 10. The epitaxial layer is composed of a silicon carbide single crystal, for example. The epitaxial layer includes an n type impurity such as nitrogen, as with the silicon carbide single crystal substrate. The impurity concentration of the epitaxial layer is, for example, not less than 1.0×10¹⁵ cm⁻³ and not more than 1.0×10¹⁶ cm⁻³. Thus, the impurity concentration in the epitaxial layer is preferably lower than the impurity concentration in the silicon carbide single crystal substrate. It should be noted that a boundary between the silicon carbide single crystal substrate and the epitaxial layer in the silicon carbide epitaxial substrate can be confirmed by measuring an impurity concentration in the thickness direction of the substrate using secondary ion mass spectroscopy (SIMS), for example.

The epitaxial layer is an epitaxial growth layer formed on first main surface 11 of the silicon carbide single crystal substrate through vapor phase epitaxy such as CVD. More specifically, the epitaxial layer is formed by CVD employing silane (SiH₄) and propane (C₃H₈) as a source material gas and nitrogen (N₂) or ammonia (NH₃) as a dopant gas. The epitaxial layer includes nitrogen (N) atoms, which are generated through thermal decomposition of the above-described nitrogen or ammonia, and therefore has n type conductivity type.

It should be noted that when first main surface 11 is angled off relative to the (0001) plane as described above, the epitaxial layer is formed through step-flow growth. Hence, the epitaxial layer is composed of 4H type silicon carbide as with the silicon carbide single crystal substrate and therefore a different type of polytype is suppressed from being mixed therein. The epitaxial layer has a thickness of about not less than 10 μm and not more than 50 μm, for example.

A plurality of pits are formed in main surface 21 of epitaxial layer 20. The plurality of pits includes: pits each having a relatively deep depth from the main surface; and pits each having a relatively shallow depth from the main surface.

Each of the deep pits has a maximum depth of not less than 8 nm from the main surface. This maximum depth is the maximum depth of the entire pit. On the other hand, each of the shallow pits has a maximum depth of less than 8 nm from the main surface.

Each of the pits formed in the main surface has a side surface. The side surface is inclined relative to the main surface, with the result that the pit is expanded in a tapered manner toward the opening. The side surface of the pit includes the {0001} plane.

Here, the pits formed in the main surface of the epitaxial layer are originated from the threading dislocations mainly in the epitaxial layer. Examples of representative dislocations in a 4H type silicon carbide single crystal include threading screw dislocations (TSD), threading edge dislocations (TED), and basal plane dislocations (BPD). These dislocations are included in the 4H type silicon carbide single crystal substrate, and are propagated and transferred to the epitaxial layer. During the propagation, the structures of these dislocations may be transformed in various manners.

The threading screw dislocations (TSD) are propagated in the 4H type silicon carbide single crystal in substantially the c axis direction. Most of the threading screw dislocations in the 4H type silicon carbide single crystal substrate are transferred into the epitaxial layer without a change during the epitaxial growth as shown in FIG. 2. Due to the threading screw dislocations having been propagated in the epitaxial layer, the relatively deep pits are formed in the main surface of the epitaxial layer.

The threading edge dislocations (TED) are propagated in the 4H type silicon carbide single crystal in substantially the c axis direction. On the other hand, the basal plane dislocations (BPD) are propagated in the basal plane ((0001) plane) within the 4H type silicon carbide single crystal. Since the threading edge dislocation and the basal plane dislocation have equal Burgers vectors, the respective structures of the threading edge dislocation and the basal plane dislocation can be transformed therebetween. In the epitaxial growth using the off substrate having the first main surface inclined relative to the basal plane, most of the basal plane dislocations in the substrate are transformed into the threading edge dislocations as shown in FIG. 2. On the other hand, most of the threading edge dislocations in the substrate are propagated in the epitaxial layer while unchanged from the threading edge dislocations. Due to the threading edge dislocations transformed from the basal plane dislocations and the threading edge dislocations propagated in the epitaxial layer, the relatively shallow pits are formed in the main surface of the epitaxial layer.

The area density of the deep pits in the main surface is preferably not more than 1000 cm⁻², is more preferably not more than 100 cm⁻², and is further preferably not more than 10 cm⁻². As described above, the deep pits are originated from the threading screw dislocations mainly existing in the epitaxial layer, whereas the shallow pits are originated from the threading edge dislocations mainly existing in the epitaxial layer. Accordingly, in order to reduce the area density of the deep pits in the main surface to the above-described range, it is effective to reduce the threading screw dislocation density in the epitaxial layer to the above-described range. On the other hand, since the threading edge dislocation density in the epitaxial layer is not required to be reduced, the threading edge dislocation density in the epitaxial layer is preferably higher than the threading screw dislocation density in the epitaxial layer. Preferably, the threading edge dislocation density in the epitaxial layer is not less than 1000 cm⁻², and is more preferably not less than 3000 cm⁻².

It should be noted that the threading screw dislocation density and threading edge dislocation density in the epitaxial layer can be measured by counting the number of etch pits resulting from etching performed by immersing the silicon carbide epitaxial substrate in molten KOH heated at 520° C. for 5 minutes, for example.

### Fourth Embodiment

### Overview of Fourth Embodiment

A fourth embodiment of the present disclosure is listed and described.

[1] A silicon carbide epitaxial substrate includes: a silicon carbide single crystal substrate having a first main surface; and an epitaxial layer formed on the silicon carbide single crystal substrate and having a main surface opposite to the silicon carbide single crystal substrate. The epitaxial layer has a thickness of not less than 10 μm. In the main surface, pits are formed to each have a maximum depth of not less than 8 nm from the main surface. The area density of the pits in the main surface is not more than 1000 cm⁻². A ratio of a standard deviation of the carrier concentration in a plane of the epitaxial layer to an average value of the carrier concentration in the plane is not more than 10%.

According to this silicon carbide epitaxial substrate, both suppression of the deep pits and the in-plane uniformity of the carrier concentration can be attained. Accordingly, reliability of semiconductor devices can be improved while maintaining yield of the semiconductor devices.

The breakdown voltage of each semiconductor device is dependent on the carrier concentration of the epitaxial layer. When the in-plane uniformity of the carrier concentration becomes low in the epitaxial layer, the breakdown voltages of the semiconductor devices are varied, thus affecting the yield. Hence, when growing the epitaxial layer, it is necessary to select a condition under which the in-plane uniformity of the carrier concentration becomes as high as possible.

Improvement in reliability of a semiconductor device has also been desired. However, in a research by the present inventor, it is found that the in-plane uniformity of the carrier concentration and the reliability of the semiconductor device have a trade-off relation. That is, when the epitaxial layer is grown under such a condition that the in-plane uniformity of the carrier concentration becomes high, minute defects (pits) each in the form of a groove are likely to be generated in the surface of the epitaxial layer. When an oxide film is formed on such an epitaxial layer, the film thickness of the oxide film is varied around the deep pits. In the oxide film at its portion having a thin film thickness, an electric field is likely to be concentrated. Hence, it is also considered that when the deep pits are increased, the life of the oxide film is decreased.

Here, the present inventor has found the following new knowledge about the pits. The depth of a pit is dependent on a condition for growing the epitaxial layer. The pit is formed only in the surface of the epitaxial layer. When the maximum depth of the pit from the surface of the epitaxial layer becomes not less than 8 nm, the pit causes a variation in the thickness of the oxide film.

The “in-plane uniformity of the carrier concentration” can be evaluated in accordance with the ratio of the standard deviation (σ) of the carrier concentration in the plane of the epitaxial layer to the average value (ave) of the carrier concentration in the plane. That is, as the percentage of the value (σ/ave) obtained by dividing the standard deviation (σ) by the average value (ave) is a lower value, the in-plane uniformity of the carrier concentration can be evaluated to be higher. According to the research by the present inventor, yield of semiconductor devices can be maintained when the percentage of “σ/ave” is not more than 10%.

[2] The silicon carbide single crystal substrate may have a diameter of not less than 100 mm and not more than 200 mm.

[3] The epitaxial layer may have a thickness of not more than 200 μm.

[4] The carrier concentration may be not less than 1×10¹⁴ cm⁻³ and not more than 1×10¹⁶ cm⁻³

[5] The first main surface may correspond to a (000-1) plane or a plane inclined by not less than 1° and not more than 8° relative to the (000-1) plane.

[6] A silicon carbide epitaxial substrate includes: a silicon carbide single crystal substrate having a first main surface and having a diameter of not less than 100 mm and not more than 200 mm; and an epitaxial layer formed on the silicon carbide single crystal substrate and having a main surface opposite to the silicon carbide single crystal substrate. The epitaxial layer has a thickness of not less than 10 μm and not more than 200 μm. In the main surface, pits are formed to each have a maximum depth of not less than 8 nm from the main surface. An area density of the pits in the main surface is not more than 1000 cm⁻². A ratio of a standard deviation of the carrier concentration in a plane of the epitaxial layer to an average value of the carrier concentration in the plane is not more than 10%.

According to this silicon carbide epitaxial substrate, both suppression of the deep pits and the in-plane uniformity of the carrier concentration can be attained.

### Details of Fourth Embodiment

[Silicon Carbide Epitaxial Substrate]

As shown in FIG. 2, a silicon carbide epitaxial substrate 100 includes: a silicon carbide single crystal substrate 10; and an epitaxial layer 20 formed on silicon carbide single crystal substrate 10.

[Silicon Carbide Single Crystal Substrate]

Silicon carbide of silicon carbide single crystal substrate 10 desirably has a polytype of 4H-SiC because 4H-SiC is more excellent than other polytypes in terms of electron mobility, dielectric strength, and the like. Silicon carbide single crystal substrate 10 may have a diameter of not less than 100 mm. When the diameter thereof is not less than 100 mm, manufacturing cost of semiconductor devices may be reduced. From the same point of view, the diameter of silicon carbide single crystal substrate 10 may be not less than 150 mm. The diameter of silicon carbide single crystal substrate 10 may be not more than 200 mm. When the diameter thereof is not more than 200 mm, yield of semiconductor devices may be improved.

Silicon carbide single crystal substrate 10 has a first main surface 11. Epitaxial layer 20 is formed on first main surface 11. First main surface 11 may correspond to a (0001) plane or a plane inclined by not less than 1° and not more than 80 relative to the (0001) plane. The (0001) plane is also referred to as “silicon plane”. By growing the epitaxial layer at the silicon plane side, inclusion of an impurity to serve as a background can be suppressed.

First main surface 11 preferably corresponds to a plane inclined by not less than 1° and not more than 8° relative to the (0001) plane. That is, silicon carbide single crystal substrate 10 preferably has an off angle of not less than 1° and not more than 8°. By introducing the off angle into silicon carbide single crystal substrate 10, step-flow growth is induced in first main surface 11. Accordingly, a different polytype can be suppressed from being mixed therein. A direction in which the off angle is provided is desirably a <11-20> direction. The upper limit of the off angle is more preferably 70, is particularly preferably 6°, and is most preferably 5°. The lower limit of the off angle is more preferably 2°, and is particularly preferably 3°

[Epitaxial Layer]

Epitaxial layer 20 is a silicon carbide single crystal layer grown epitaxially on first main surface 11. The epitaxial layer contains nitrogen (N) as a dopant, for example.

The epitaxial layer has a thickness of not less than 10 μm. When the thickness of the epitaxial layer is less than 10 μm, it may be difficult to maintain the high in-plane uniformity of the carrier concentration while suppressing generation of the deep pits. The lower limit of the thickness of epitaxial layer 20 may be 20 μm or 50 μm. The upper limit of the thickness of the epitaxial layer may be 200 μm, 150 μm, or 100 μm.

Epitaxial layer 20 has a main surface 21 opposite to silicon carbide single crystal substrate 10. Pits are formed in the main surface. The pits are roughly classified into: deep pits each having a maximum depth of not less than 8 nm from the main surface; and shallow pits each having a maximum depth of less than 8 nm from the main surface. According to a research by the present inventor, life of an oxide film is affected mainly by such deep pits.

In the fourth embodiment, the area density of the deep pits in the main surface is not more than 1000 cm⁻². Accordingly, reliability of a semiconductor device manufactured using silicon carbide epitaxial substrate 100 can be improved. A lower area density of deep pits is more preferable, and the area density is ideally 0. The area density of the deep pits is preferably not more than 100 cm⁻², is more preferably 10 cm⁻², is particularly preferably not more than 1 cm⁻², and is most preferably not more than 0.1 cm⁻².

The in-plane uniformity of the carrier concentration in the epitaxial layer, i.e., the percentage of c/ave is not more than 10%. Accordingly, yield of semiconductor devices can be maintained. A smaller percentage of “6/ave” is more preferable, and the percentage is ideally 0. The percentage of “σ/ave” is more preferably not more than 8%, is particularly preferably not more than 6%, and is most preferably not more than 4%.

The carrier concentration of the epitaxial layer may be not less than 1×10¹⁴ cm⁻³ and not more than 1×10¹⁶ cm⁻³. By setting the carrier concentration at not more than 1×10¹⁶ cm⁻³, a semiconductor device having a high breakdown voltage may be realized. In view of on resistance of the semiconductor device, the carrier concentration may be not less than 1×10¹⁴ cm⁻³. The upper limit of the carrier concentration may be 8×10¹⁵ cm⁻³ or 5×10¹⁵ cm⁻³. The lower limit of the carrier concentration may be 5×10¹⁴ cm⁻³ or 1×10¹⁵ cm⁻³.

The background concentration of the dopant is preferably not more than 1×10¹⁴ cm⁻³. The background of the dopant refers to a dopant other than the dopant intentionally introduced in the epitaxial layer. For example, nitrogen or the like released from a member in a CVD apparatus and included in the epitaxial layer is the background. The background concentration can be measured by growing the epitaxial layer without supplying a dopant gas and by analyzing the dopant concentration in the epitaxial layer through SIMS.

The in-plane uniformity of the carrier concentration can be improved by setting the background concentration at not more than 1×10¹⁴ cm⁻³. A lower background concentration is more preferable. The background concentration is more preferably not more than 8×10¹³ cm⁻³, and is particularly preferably not more than 5×10¹³ cm⁻³

### MODIFICATION

Next, a modification of the fourth embodiment will be described. The following mainly describes a difference from the description above, and the same explanation will not be repeatedly made.

In the silicon carbide epitaxial substrate according to the modification, first main surface 11 of silicon carbide single crystal substrate 10 corresponds to a (000-1) plane or a plane inclined by not less than 1° and not more than 8° relative to the (000-1) plane. The (000-1) plane is referred to as “carbon plane”. Generally, in the epitaxial growth at the carbon plane side, nitrogen is more likely to be included therein from outside to serve as an impurity, as compared with the epitaxial growth at the silicon plane side. Therefore, in the epitaxial layer grown at the carbon plane side, it is difficult to maintain the high in-plane uniformity of the carrier concentration.

However, according to the present embodiment, the in-plane uniformity of the carrier concentration can be maintained to be high also in the epitaxial layer grown at the carbon plane side. In the epitaxial layer grown at the carbon plane side, improvement in channel mobility or the like can be expected.

The diameter of silicon carbide single crystal substrate 10 according to the modification may be not less than 100 mm or not more than 200 mm. Epitaxial layer 20 has a main surface 21. The area density of the pits in the main surface is not more than 1000 cm⁻².

Although epitaxial layer 20 according to the modification is an epitaxial layer grown at the carbon plane side, the percentage of the value (σ/ave) obtained by dividing the standard deviation of the carrier concentration by the average value thereof is not more than 10%. For example, in a silicon carbide epitaxial substrate having a diameter of 6 inches, the percentage of c/ave when measuring the carrier concentration at 25 points in the plane can be reduced to not more than 3%.

Here, the 25 measurement points in the plane are set as follows. First, assuming that the planar shape of the silicon carbide epitaxial substrate is circular, a first straight line is drawn to pass through the central point of the circle and extend across the main surface. Next, a second straight line is drawn to pass through the central point of the circle, be orthogonal to the first straight line, and extend across the main surface. Six measurement points are set at an interval of 10 mm from the central point of the circle to one end of the line on the first straight line. Likewise, six measurement points are set at an interval of 10 mm from the central point of the circle to the other end of the line. Accordingly, a total of 12 measurement points are set on the first straight line. In the same manner, a total of 12 measurement points are set on the second straight line. In this way, the 25 measurement points including the central point of the circle and the 24 measurement points are set in the plane.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: shallow pit; 2: deep pit; 5: measurement point; 10: silicon carbide single crystal substrate; 11: first main surface; 12: second main surface; 20: epitaxial layer; 21: main surface; 30: circular pit; 40: triangular pit; 50: bar-like pit; 51: first width; 52: second width; 91: first arrow; 92: second arrow; 93: third arrow; 94: fourth arrow; 95: fifth arrow; 96: sixth arrow; 97: seventh arrow; 98: eighth arrow; 100: silicon carbide epitaxial substrate; 101: first layer; 102: second layer; 200: CVD apparatus; 202: channel; 203: induction heating coil; 204: quartz tube; 205: heat insulator; 207: curved portion; 208: flat portion; 210: susceptor; 211: first base member; 212: first coating portion; 220: heating element; 221: second base member; 222: second coating portion; 256: pipe; 257: preheating structure; 301: dashed line; 302: dotted line; 303: solid line.

1. A silicon carbide epitaxial substrate comprising:
a silicon carbide single crystal substrate; and
an epitaxial layer on the silicon carbide single crystal substrate,
the silicon carbide single crystal substrate having a diameter of not less than 100 mm,
the epitaxial layer having a thickness of not less than 10 μm,
the epitaxial layer having a carrier concentration of not less than 1×10¹⁴ cm⁻³ and not more than 1×10¹⁶ cm⁻³,
a ratio of a standard deviation of the carrier concentration in a plane of the epitaxial layer to an average value of the carrier concentration in the plane being not more than 10%,
the epitaxial layer having a main surface,
the main surface having an arithmetic mean roughness Sa of not more than 0.3 nm in three-dimensional surface roughness measurement,
an area density of pits originated from a threading screw dislocation being not more than 1000 cm⁻² in the main surface,
each of the pits having a maximum depth of not less than 8 nm from the main surface.

2. The silicon carbide epitaxial substrate according to claim 1, wherein the area density is not more than 100 cm⁻².

3. The silicon carbide epitaxial substrate according to claim 1, wherein the area density is not more than 10 cm⁻².

4. The silicon carbide epitaxial substrate according to claim 1, wherein the area density is not more than 1 cm⁻².

5. The silicon carbide epitaxial substrate according to claim 1, wherein the diameter is not less than 150 mm.

6. The silicon carbide epitaxial substrate according to claim 1, wherein the diameter is not less than 200 mm.

7. The silicon carbide epitaxial substrate according to claim 1, wherein the ratio is not more than 5%.

8. The silicon carbide epitaxial substrate according to claim 1, wherein the maximum depth is not less than 20 nm.

9. The silicon carbide epitaxial substrate according to claim 1, wherein
each of the pits has a planar shape including a first width and a second width, the first width extending in a first direction, the second width extending in a second direction perpendicular to the first direction, and
the first width is twice or more as large as the second width.

10. A silicon carbide epitaxial substrate comprising:
a silicon carbide single crystal substrate; and
an epitaxial layer on the silicon carbide single crystal substrate,
the silicon carbide single crystal substrate having a diameter of not less than 100 mm,
the epitaxial layer having a thickness of not less than 10 μm,
the epitaxial layer having a carrier concentration of not less than 1×10¹⁴ cm⁻³ and not more than 1×10¹⁶ cm⁻³,
a ratio of a standard deviation of the carrier concentration in a plane of the epitaxial layer to an average value of the carrier concentration in the plane being not more than 10%,
the epitaxial layer having a main surface,
the main surface having an arithmetic mean roughness Sa of not more than 0.3 nm in three-dimensional surface roughness measurement,
an area density of pits originated from a threading screw dislocation being not more than 1000 cm⁻² in the main surface,
each of the pits having a planar shape including a first width and a second width, the first width extending in a first direction, the second width extending in a second direction perpendicular to the first direction,
the first width being twice or more as large as the second width,
each of the pits having a maximum depth of not less than 20 nm from the main surface.
